(19) United States
(12) Patent Application Publication
(10) Pub. No.: US 2007/0040707 A1
(43) Pub. Date: Feb. 22, 2007

(54) Separation of Components and Characters in Chinese Text Input

(76) Inventor: Jenny Huang-Yu Lai, Seattle, WA (US)

Correspondence Address: GLENN PATENT GROUP, 3475 EDISON WAY, SUITE L, MENLO PARK, CA, 94025, US

(21) Appl. No.: 11/464,748

(22) Filed: Aug. 15, 2006

Related U.S. Application Data
(60) Provisional application No. 60/708,917, filed on Aug. 16, 2005.

(51) Int. Cl. H03K 17/94; G06F 17/20

(52) U.S. Cl. 341/28; 704/8

(57) ABSTRACT

Components and characters are separated in a user interface for stroke based input of Chinese characters. A user enters a stroke sequence, and matching components and characters are separately displayed in separate selection lists. When the user selects a component, the character selection list is updated to only display characters that contain that component. This input methodology can be implemented on mobile phones, as well as other computing devices such as personal digital assistants. More characters are visible in the character selection list, which aids all users. Of further benefit to those who do use components, more components are displayed as components and characters do not need to share selection list space. Furthermore, separating components and characters reduces confusion between characters and components that look similar.

### PRIORITY CLAIM AND RELATED APPLICATION

This patent application claims the benefit of provisional application Ser. No. 60/708,917, titled “User Interface for Chinese Text Input,” filed on Aug. 16, 2005, the entirety of which is hereby incorporated by reference.

### TECHNICAL FIELD

This invention pertains generally to user interfaces, and more specifically to separating components and characters in an interface for inputting Chinese text.

### BACKGROUND

With the immense popularity of mobile phones, the usage of text messages has grown tremendously in the last several years, especially in China. According to recent statistics, there are over 330 million mobile subscribers in China. In 2004, Chinese mobile subscribers sent 217.76 billion text messages, a 58.8% year on year increase. More recently, in February 2005, 11 billion text messages were sent in China during the week of Chinese Lunar New Year.

An essential part of the text messaging experience is text input on mobile phones. Because of the sheer number of Chinese text input users using text messaging on mobile phones and the phenomenal growth in the number of Chinese text messages sent from mobile phones, Chinese text input performance on mobile phones is of great commercial importance today.

Because Chinese is an ideographic language, Chinese text input is more complicated than alphabetic text input. Current Chinese text input methods on mobile phones usually follow either the phonetic approach or the stroke approach in the phonetic approach, the pronunciation of Chinese characters is used to help the user find the desired character. Pinyin, a standard Chinese phonetic system that uses alphabetic letters, is widely used in China. With Pinyin, the user uses alphabetic letters to construct the pronunciation of a Chinese character, then chooses the desired character from a list of character candidates.

In the stroke approach, Chinese characters are decomposed into strokes. Stroke categories are mapped to keys on the keypad. The user uses stroke categories to enter the strokes of a character, and can then choose the desired character from a selection list. These mobile text input systems typically also display components of characters among the characters that match the current stroke (key) sequence. When the user selects a component, the corresponding stroke sequence (typically displayed) is replaced with the component; additional strokes may be entered but only the characters containing the selected component will match.

Both the phonetic and stroke approaches can accommodate Simplified Chinese, used primarily in mainland China, and Traditional Chinese, used primarily in Taiwan and Hong Kong. Phonetically, equivalent characters in Simplified and Traditional Chinese usually have the same pronunciation in Mandarin. In contrast, with the stroke approach, equivalent characters in Simplified and Traditional Chinese often have drastically different strokes, stroke numbers and stroke sequences.

Currently, there are three major stroke-based Simplified Chinese input methods on mobile phones available in the market. These input methods decompose characters using different stroke categories; the stroke categories used by the three methods are displayed in FIGS. 1A-C. Method A uses 5 stroke categories: horizontal stroke (Key 1), vertical stroke (Key 2), left-to-right stroke (Key 3), right-to-left stroke (Key 4), stroke with changes in direction (Key 5) plus a wildcard key (Key 6). Method B uses horizontal stroke (Key 1), vertical stroke (Key 2), left-to-right stroke (Key 3), right-to-left stroke (Key 4), horizontal-down stroke (Key 5), curved stroke (Key 6), vertical-right stroke (Key 7), multi-bend (Key 9) stroke, plus a wildcard key (Key 8). Method C uses 9 stroke categories: 1-bend stroke (Key 1), dot (Key 2), horizontal-down stroke (Key 3), right-to-left (Key 4), vertical stroke (Key 5), left-to-right (Key 6), vertical stroke with a hook (Key 7), horizontal stroke (Key 8), and multi-bend stroke (Key 9).

As noted above, in the current stroke based input systems, components and characters are lumped together in the same selection list. When a component is selected, the content of the selection list is updated to include characters that begin with the selected component. These systems use an integrated selection list that contains both components and characters, as illustrated in FIG. 2. To distinguish components and characters, components are displayed, for example, with dashed underlines in the selection list. The content of the selection list is filtered if a component is selected.

Displaying both components and characters together can be confusing, as some characters and components look similar. Furthermore, some users do not use components at all. For these users, having components on the screen along with the characters takes up valuable screen space that could be used to display additional characters. Knowing how to use components helps users transition to using a different input method with a different set of stroke categories. However, many users cannot figure out how to use components without assistance.

What is needed are methods and systems that make it easier to distinguish components from characters, do not reduce the number of characters visible to users, and make it easier to learn how to use components.

### SUMMARY OF INVENTION

Computer-implemented methods, computer systems and computer-readable media separate components and characters in stroke based input of Chinese characters. A user enters a stroke sequence, and matching components and characters are separately displayed in separate selection lists. When the user selects a component, the character selection list is updated to only display characters that contain that component. This input methodology can be implemented on mobile phones, as well as other computing devices such as personal digital assistants.

The separation of components and characters benefits both those who routinely use components in the entry of Chinese characters and those who do not. More characters are visible in the character selection list, which aids all users. Of further benefit to those who do use components, more components are displayed as components and characters do not need to share selection list space. Furthermore, separating components and characters reduces confusion between characters and components that look similar. Additionally, the separation of components and characters makes it easier for users to learn how to use components.

The features and advantages described in this summary and in the following detailed description are not all-inclusive, and particularly, many additional features and advantages will be apparent to one of ordinary skill in the relevant art in view of the drawing, specification, and claims hereof. Moreover, it should be noted that the language used in the specification has been principally selected for readability and instructional purposes, and may not have been selected to delineate or circumscribe the inventive subject matter, resort to the claims being necessary to determine such inventive subject matter.

### BRIEF DESCRIPTION OF THE DRAWINGS

FIGS. 1A-C illustrate key layouts for five, eight and nine stroke category input respectively.

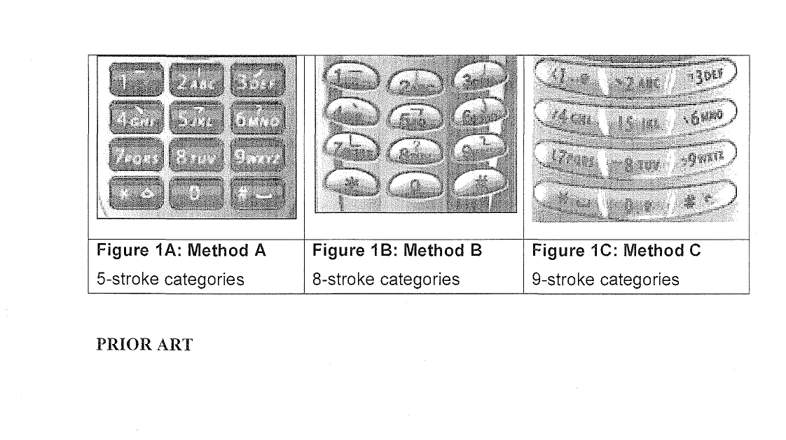

FIG. 2 illustrates a prior art interface in which components and characters are displayed in a single selection list.

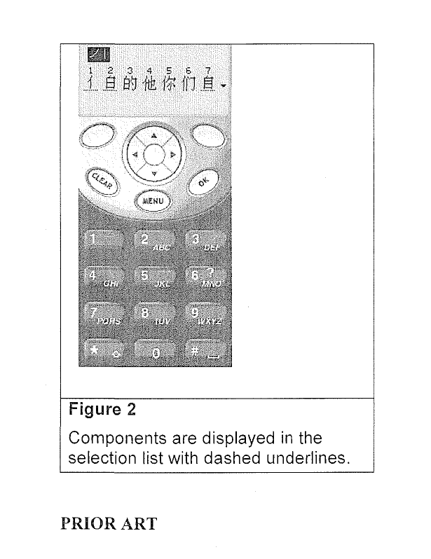

FIG. 3 illustrates an interface in which components and characters are separated, according to one embodiment of the present invention.

The Figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION

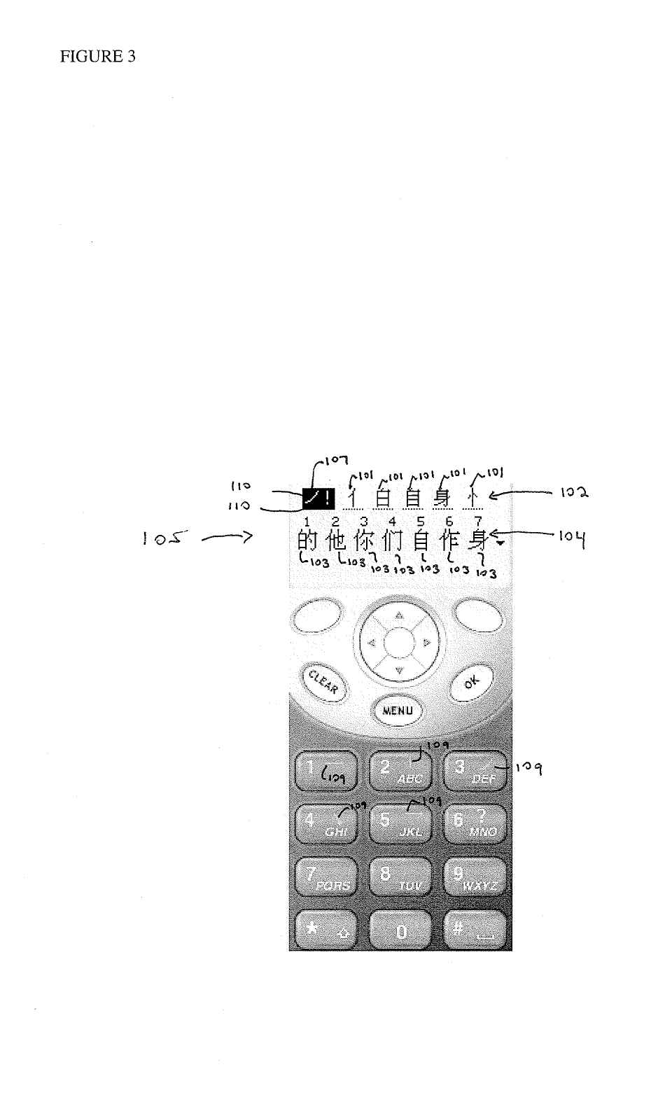

As illustrated in FIG. 3, in one embodiment of the present invention, components 101 and characters 103 are separated on a user interface 105, such that a separate component selection list 102 and a separate character selection list 104 are displayed. For example, as illustrated in FIG. 3, the components 101 are displayed in a separate row above the characters 103. As will be understood by those of ordinary skill in the relevant art in light of this specification, components 101 and characters 103 can be separated in other ways as well, for example by displaying the components 101 under the characters 103, or in separate columns or boxes, etc.

As illustrated in FIG. 3, a current entered stroke sequence 107 is shown on the interface 105 (for example, the illustrated sequence 107 is made up of two strokes 110). The separate listings 102, 104 of both components 101 and characters 103 are filtered such that only those that match the stroke sequence 107 are displayed. If the user then selects a component 101, the character selection list 104 is filtered based on the selected component 101.

Users need not select components 101. A user can simply work with strokes 110 and characters 103 if the user so prefers. However, as noted above, when a user does select a component 101, then only the characters 103 containing the selected component 101 will be displayed in the character selection list 104.

Note that with the separation of characters 103 and components 101 as per the present invention, those who rarely or never use components 101 will still benefit because more characters 103 will be visible in the character selection list 104. Of benefit to those who do use components 101, more components 101 can be shown because components 101 do not need to share selection list space with characters 103. Also, separating components 101 and characters 103 reduces confusion between characters 103 and components 101 that look similar.

Furthermore, the present invention makes it easier for users to learn how to use components 101. As noted above, many users cannot figure out how to use components 101 in non-separation systems without assistance. Knowing how to use components 101 helps users transition to using a different input method with a different set of stroke categories 109. Users can rely on components 101 if they are unsure how to map a character stroke 110 to the stroke categories 109 provided by an input method.

In one embodiment of the present invention, if an additional stroke 110 is entered after a component 101 has been selected, the preceding stroke sequence 107 (which corresponds to the selected component 101) is replaced on the interface 105 by an updated sequence 107 including the newly entered stroke 110. The selection lists 102, 104 are updated accordingly.

In one embodiment, the character selection list 104 includes only characters 103 in which the selected component 101 comprises the beginning of the stroke sequence 107 for the character. In another embodiment, the character selection list 104 includes characters 103 that include the selected component 101 anywhere in the stroke sequence 107, not only at the beginning.

In yet another embodiment, pairs of components 101 are shown in the component selection list 102 if the entered stroke sequence 107 matches all of the first component 101 and a part of the second component 101. As will be understood by those of ordinary skill in the relevant art in light of this specification, entered stroke sequences 107 can also be used in other embodiments to match combinations of multiple components 101 in other, similar ways as well. Furthermore, selected components 101 can be used to match individual characters 103 as described above, or entire phrases (not illustrated).

Some embodiments of the present invention, by separating components 101 and characters 103, further support the entry of characters 103 by selecting components 101 and specifying the number of remaining strokes 110 in the character 103 (rather than entering the additional strokes 110). If the user is not sure how to map a stroke 110 to a stroke category 109, the user can simply enter the count of remaining strokes 109. This is one way people look up a word in a Chinese dictionary.

In another embodiment, the separation of components 101 and characters 103 is also used to display strokes 110 included a stroke category 109. In this embodiment, responsive to a key press indicating a stroke category 109, the component list 102 can also show all the strokes 110 that are included in the stroke category 109. This helps users learn how to use the current stroke category input method more effectively. For example, with an implementation of the 5 stroke category 109, many users do not realize that the lower-left-to-upper-right stroke 110 belongs in the horizontal stroke category 109.

It will be apparent to those of ordinary skill in the relevant art in light of this specification that the various embodiments of present invention can be implemented not only on mobile phones as illustrated, but also on other computing devices such as personal digital assistants and the like. The interface 105 can include a touch screen for selecting components 101 and characters 103, or users can make selections using key presses or by operating a pointing device, etc. The separation of components 101 and characters 103 according the present invention can be implemented for five, eight, nine or other stroke categories 109, and with simplified or traditional Chinese.

As will be understood by those familiar with the art, the invention may be embodied in other specific forms without departing from the spirit or essential characteristics thereof. Likewise, the particular naming and division of the modules, agents, managers, functions, procedures, actions, layers, features, attributes, methodologies and other aspects are not mandatory or significant, and the mechanisms that implement the invention or its features may have different names, divisions and/or formats. Furthermore, as will be apparent to one of ordinary skill in the relevant art, the modules, agents, managers, functions, procedures, actions, layers, features, attributes, methodologies and other aspects of the invention can be implemented as software, hardware, firmware or any combination of the three. Of course, wherever a component of the present invention is implemented as software, the component can be implemented as a script, as a standalone program, as part of a larger program, as a plurality of separate scripts and/or programs, as a statically or dynamically linked library, as a kernel loadable module, as a device driver, and/or in every and any other way known now or in the future to those of skill in the art of computer programming. Additionally, the present invention is in no way limited to implementation in any specific programming language, or for any specific operating system or environment. Accordingly, the disclosure of the present invention is intended to be illustrative, but not limiting, of the scope of the invention, which is set forth in the following claims.

What is claimed is:

1. A computer implemented method for stroke based input of Chinese characters, the method comprising the steps of:
displaying an entered stroke sequence;
displaying components that match the entered stroke sequence on a component selection list; and
separately displaying characters that match the entered stroke sequence on a separate character selection list.

2. The method of claim 1 further comprising:
responsive to selection of a component, updating the character selection list to display only characters that match the selected component.

3. The method of claim 2 further comprising:
responsive to entry of an additional stroke after selection of a component:
updating the displayed stroke sequence to include the additional entered stroke;
updating the component selection list to display only components that match the updated stroke sequence; and
updating the character selection list to display only characters that match the updated stroke sequence.

4. The method of claim 2 wherein updating the character selection list to display only characters that match the selected component further comprises:
updating the character selection list to display only characters for which the selected component begins a stroke sequence.

5. The method of claim 2 wherein updating the character selection list to display only characters that match the selected component further comprises:
updating the character selection list to display only characters for which the selected component is a part of a stroke sequence.

6. The method of claim 1 wherein displaying components that match the entered stroke sequence on a component selection list further comprises:
displaying at least one set of multiple components that together match the entered stroke sequence.

7. The method of claim 2 wherein updating the character selection list to display only characters that match the selected component further comprises:
updating the character selection to display at least one set of multiple characters that together match the selected component.

8. The method of claim 2 wherein updating the character selection list to display only characters that match the selected component further comprises:
receiving an indication of a number of remaining strokes in a target character, in addition to the selected component; and
updating the character selection to display only characters that match the selected component and contain the number of remaining strokes.

9. The method of claim 1 further comprising:
responsive to receiving an indication of an entry of a stroke category, displaying strokes included in the indicated stroke category.

10. The method of claim 1 wherein:
the method is instantiated on a computing device from a group of computing devices consisting of:
a mobile phone;
a personal digital assistant; and
a handheld computer.

11. A computer system for stroke based input of Chinese characters, the computer system comprising:
a portion configured to display an entered stroke sequence;
a portion configured to display components that match the entered stroke sequence on a component selection list; and
a portion configured to separately display characters that match the entered stroke sequence on a separate character selection list.

12. The computer system of claim 11 further comprising:
a portion configured to, responsive to selection of a component, update the character selection list to display only characters that match the selected component.

13. The computer system of claim 12 further comprising:
a portion configured to, responsive to entry of an additional stroke after selection of a component:
update the displayed stroke sequence to include the additional entered stroke;
update the component selection list to display only components that match the updated stroke sequence; and
update the character selection list to display only characters that match the updated stroke sequence.

14. The computer system of claim 12 wherein the portion configured to update the character selection list to display only characters that match the selected component is further configured to:
update the character selection list to display only characters for which the selected component begins a stroke sequence.

15. The computer system of claim 12 wherein the portion configured to update the character selection list to display only characters that match the selected component is further configured to:
update the character selection list to display only characters for which the selected component is a part of a stroke sequence.

16. The computer system of claim 11 wherein the portion configured to display components that match the entered stroke sequence on a component selection list is further configured to:
display at least one set of multiple components that together match the entered stroke sequence.

17. The computer system of claim 12 wherein the portion configured to update the character selection list to display only characters that match the selected component is further configured to:
update the character selection to display at least one set of multiple characters that together match the selected component.

18. The computer system of claim 12 wherein the portion configured to update the character selection list to display only characters that match the selected component is further configured to:
receive an indication of a number of remaining strokes in a target character, in addition to the selected component; and
update the character selection to display only characters that match the selected component and contain the number of remaining strokes.

19. The computer system of claim 11 further comprising:
a portion configured to receive an indication of an entry of a stroke category; and
a portion configured to displaying strokes included in the indicated stroke category.

20. The computer system of claim 11 wherein the computing system is one from a group consisting of:
a mobile phone;
a personal digital assistant; and
a handheld computer.

21. At least one computer readable medium containing a computer program product for stroke based input of Chinese characters, the computer program product comprising:
program code for displaying an entered stroke sequence;
program code for displaying components that match the entered stroke sequence on a component selection list; and
program code for separately displaying characters that match the entered stroke sequence on a separate character selection list.

22. The computer program product of claim 21 further comprising:
program code for responsive to selection of a component, updating the character selection list to display only characters that match the selected component.

23. The computer program product of claim 22 further comprising:
program code for, responsive to entry of an additional stroke after selection of a component:
updating the displayed stroke sequence to include the additional entered stroke;
updating the component selection list to display only components that match the updated stroke sequence; and
updating the character selection list to display only characters that match the updated stroke sequence.

24. The computer program product of claim 22 wherein the program code for updating the character selection list to display only characters that match the selected component further comprises:
program code for updating the character selection list to display only characters for which the selected component begins a stroke sequence.

25. The computer program product of claim 22 wherein the program code for updating the character selection list to display only characters that match the selected component further comprises:
program code for updating the character selection list to display only characters for which the selected component is a part of a stroke sequence.

26. The computer program product of claim 21 wherein the program code for displaying components that match the entered stroke sequence on a component selection list further comprises:
program code for displaying at least one set of multiple components that together match the entered stroke sequence.

27. The computer program product of claim 22 wherein the program code for updating the character selection list to display only characters that match the selected component further comprises:
program code for updating the character selection to display at least one set of multiple characters that together match the selected component.

28. The computer program product of claim 22 wherein the program code for updating the character selection list to display only characters that match the selected component further comprises:
program code for receiving an indication of a number of remaining strokes in a target character, in addition to the selected component; and
program code for updating the character selection to display only characters that match the selected component and contain the number of remaining strokes.

29. The computer program product of claim 21 further comprising:
program code for, responsive to receiving an indication of an entry of a stroke category, displaying strokes included in the indicated stroke category.
